(19) United States
(12) Patent Application Publication
(10) Pub. No.: US 2015/0012233 A1
(43) Pub. Date: Jan. 8, 2015

(54) SLAVE SUITABLE FOR ENERGY MANAGEMENT SYSTEMS AND ENERGY MANAGEMENT SYSTEM

(71) Applicant: PANASONIC CORPORATION, Osaka (JP)

(72) Inventors: Tomoaki Mizuta, Osaka (JP); Kenji Kuniyoshi, Osaka (JP); Tomohide Furuya, Osaka (JP); Masaki Koyama, Osaka (JP); Takayuki Sasaki, Osaka (JP); Shinji Yamamoto, Osaka (JP)

(73) Assignee: Panasonic Corporation, Osaka (JP)

(21) Appl. No.: 14/379,487

(22) PCT Filed: Feb. 26, 2013
(86) PCT No.: PCT/JP2013/001138

§ 371 Date: Aug. 18, 2014

(30) Foreign Application Priority Data
Mar. 1, 2012 (JP) 2012-045769
Jul. 11, 2012 (JP) 2012-155694

(51) Int. Cl. G01R 21/133; H04B 3/54; H04B 7/24

(52) U.S. Cl. CPC G01R 21/133; H04B 7/24; H04B 3/54
USPC 702/62

(57) ABSTRACT

The slave suitable for energy management systems in accordance with the present invention is a slave of an energy management system for collecting, from an energy meter for measuring an amount of electric energy supplied from a power source to a predetermined place through a distribution line, a meter-reading data containing the amount of electric energy. The slave includes: a first interface unit configured to communicate with an upper device; a second interface unit configured to communicate with an electric appliance installed in the predetermined place; a third interface unit configured to communicate with a communication terminal. The second interface unit and the third interface unit are configured to perform wireless communication using electric waves in wireless communication schemes different from each other.

### TECHNICAL FIELD

The present invention relates to slaves suitable for energy management systems and energy management systems.

### BACKGROUND ART

In the past, there has been proposed an energy management system. In this energy management system, a slave for communication is attached to an energy meter installed in a facility, and the slave obtains meter-reading data from the energy meter and transmits the obtained meter-reading data to an upper device. Thus, the upper device collects the meter-reading data of the facility.

For example, according to a configuration disclosed in document 1 (JP 2011-250301 A), an upper device (master terminal) and a slave (slave terminal) perform power line communication with each other by use of a distribution line as a communication path, and thus the upper device obtains meter-reading data from the slave. Further, document 1 discloses another configuration in which the slave and a maintenance terminal perform wireless communication with each other and thus the maintenance terminal performs inspection, setting change, and the like of the slave (see paragraphs [0021] and [0022], and FIG. 1).

Document 1 discloses a technique of performing the inspection and the setting change of the slave by use of the maintenance terminal, and further discloses using the maintenance terminal in order to relay wireless communication. Note that, the technique disclosed in document 1 is for remote meter-reading, and accordingly the slave communicates with only the energy meter and the maintenance terminal.

In the past, in consideration of an increase in demand for energy saving and shortage of power supply, there have been demanded a function of monitoring power consumption in electric appliances used in facilities to prompt residents to save on electricity, and a function of controlling electric appliances to reduce power consumption. However, according to the technique disclosed in document 1, the slave and the maintenance are only used to allow the upper device to use the meter-reading data of the energy meter, and there is no idea that the slave and the maintenance terminal are used for energy management of the facility.

To enable communication between the slave and the electric appliance, it is necessary to form a communication path between the slave and the electric appliance. When the communication path is formed in a wired manner, additional installation of the communication path is necessary. When the communication path is formed in a wireless manner, interference between communication between the slave and the maintenance terminal and communication between the slave and the electric appliance is likely to occur.

### SUMMARY OF INVENTION

In view of the above insufficiency, the present invention has aimed to propose a slave suitable for energy management systems that allows energy management in addition to meter-reading by employing a function of communicating with an electric appliance used in a facility in addition to a function of communicating with an upper device and a maintenance terminal, and allows facilitation of installation of the slave by employing a configuration of performing wireless communication with the maintenance terminal and the electric appliance, and can prevent interference between communication with the maintenance terminal and communication with the electric appliance, and further propose an energy management system including the slave.

The slave suitable for energy management systems of the first aspect in accordance with the present invention is a slave suitable for energy management systems for collecting, from an energy meter for measuring an amount of electric energy supplied from a power source to a predetermined place through a distribution line, meter-reading data containing the amount of electric energy. The slave includes a first interface unit, a second interface unit, a third interface unit, and a controller. The first interface unit is configured to communicate with an upper device. The second interface unit is configured to communicate with an electric appliance installed in the predetermined place. The third interface unit is configured to communicate with a communication terminal. The controller has: a function of obtaining the meter-reading data from the energy meter; a function of controlling the first interface unit to send the meter-reading data to the upper device; and a function of controlling the third interface unit to send the meter-reading data to the communication terminal. The second interface unit and the third interface unit are configured to perform wireless communication using electric waves in wireless communication schemes different from each other.

According to the slave suitable for energy management systems of the second aspect in accordance with the present invention, depending on the first aspect, the wireless communication schemes are protocols.

According to the slave suitable for energy management systems of the third aspect in accordance with the present invention, depending on the first or second aspect, the first interface unit is connected to the upper device through the distribution line, and is configured to perform power line communication with the upper device through the distribution line.

According to the slave suitable for energy management systems of the fourth aspect in accordance with the present invention, depending on the third aspect, the energy meter is connected to the power source through a transformer configured to adjust electricity from the power source to electricity appropriate to the predetermined place. The distribution line includes a first path between the power source and the transformer, and a second path between the transformer and the energy meter. The upper device is connected to the second path. The first interface unit is configured to perform power line communication with the upper device through the second path.

According to the slave suitable for energy management systems of the fifth aspect in accordance with the present invention, depending on the first or second aspect, the first interface unit is configured to perform wireless communication using an electric wave with the upper device.

According to the slave suitable for energy management systems of the sixth aspect in accordance with the present invention, depending on the fifth aspect, the first interface unit and the third interface unit are configured to perform wireless communication in the same wireless communication scheme.

According to the slave suitable for energy management systems of the seventh aspect in accordance with the present invention, depending on the fifth aspect, the first interface unit and the second interface unit are configured to perform wireless communication in the same wireless communication scheme.

According to the slave suitable for energy management systems of the eighth aspect in accordance with the present invention, depending on any one of the first to seventh aspects, the controller further includes a channel selector, an interference evaluator, and a change instructor. The channel selector is configured to select a communication channel to be used for the wireless communication of at least one of the second interface unit and the third interface unit, from a plurality of channels. The interference evaluator is configured to judge whether interference of electric waves occurs in the communication channel. The change instructor is configured to provide a change instruction to the channel selector when the interference evaluator determines that the interference occurs. The channel selector is configured to change the communication channel in response to reception of the change instruction from the change instructor.

According to the slave suitable for energy management systems of the ninth aspect in accordance with the present invention, depending on the eighth aspect, the controller includes an identification information holding unit storing identification information unique to the slave. The channel selector is configured to select from the plurality of channels an initial channel as a candidate for the communication channel, depending on the identification information stored in the identification information holding unit. The channel selector is configured to, when receiving the change instruction from the change instructor, select from the plurality of channels a channel different from the initial channel, and set the selected channel as the communication channel. The channel selector is configured to, when not receiving the change instruction from the change instructor, set the initial channel as the communication channel.

According to the slave suitable for energy management systems of the tenth aspect in accordance with the present invention, according to the eighth or ninth aspect, the interference evaluator is configured to judge whether the plurality of channels includes at least one available channel that does not cause interference of the electric wave. The interference evaluator is configured to, when determining that the plurality of channels includes the available channel, provide available channel information identifying the at least one available channel to the change instructor. The change instructor is configured to select a designated available channel to be set as the communication channel from the at least one available channel identified by the available channel information, and provide the change instruction indicating the designated available channel to the channel selector. The channel selector is configured to, when receiving the change instruction from the change instructor, set the designated available channel indicated by the change instruction as the communication channel.

According to the slave suitable for energy management systems of the eleventh aspect in accordance with the present invention, depending on any one of the eighth to tenth aspects, the controller further includes a communication quality evaluator, and a power instructor. The communication quality evaluator is configured to evaluate a communication quality of the communication channel selected by the channel selector. The power instructor is configured to set an intensity of an electric wave allocated to the communication channel to a lower limit of a range of intensities allowing the communication quality evaluated by the communication quality evaluator to satisfy a predetermined condition.

According to the slave suitable for energy management systems of the twelfth aspect in accordance with the present invention, depending on any one of the eighth to eleventh aspects, the communication channel is a channel to be used in the wireless communication of the third interface unit. The channel selector is configured to select a second communication channel to be used in the wireless communication of the second interface unit, from a plurality of channels. The third interface unit is configured to judge whether use of the communication terminal is started. The change instructor is configured to, when the third interface unit determines that use of the communication terminal is started, provide to the channel selector the change instruction that indicates, as the second communication channel, a channel that does not cause interference with a channel used by the communication terminal. The channel selector is configured to, when receiving the change instruction from the change instructor, change the second communication channel to the channel indicated by the change instructor.

According to the slave suitable for energy management systems of the thirteenth aspect in accordance with the present invention, depending on any one of the eighth to twelfth aspects, each of the plurality of channel is defined by a frequency, a time slot, or a combination of a frequency and a time slot.

According to the slave suitable for energy management systems of the fourteenth aspect in accordance with the present invention, depending on the ninth aspect, the identification information is given by the upper device to the slave.

According to the slave suitable for energy management systems of the fifteenth aspect in accordance with the present invention, depending on the first to fourteenth aspects, the slave is attached to the energy meter.

The energy management system of the sixteenth aspect in accordance with the present invention includes a slave, an upper device, and a communication terminal. The slave is configured to obtain, from an energy meter for measuring an amount of electric energy supplied from a power source to a predetermined place through a distribution line, meter-reading data containing the amount of electric energy. The upper device is configured to obtain the meter-reading data from the slave. The communication terminal is configured to obtain the meter-reading data from the slave. The slave includes a first interface unit, a second interface unit, a third interface unit, and a controller. The first interface unit is configured to communicate with the upper device. The second interface unit is configured to communicate with an electric appliance installed in the predetermined place. The third interface unit is configured to communicate with the communication terminal. The controller has: a function of obtaining the meter-reading data from the energy meter; a function of controlling the first interface unit to send the meter-reading data to the upper device; and a function of controlling the third interface unit to send the meter-reading data to the communication terminal. The second interface unit and the third interface unit are configured to perform wireless communication using electric waves in wireless communication schemes different from each other.

According to the energy management system of the seventeenth aspect in accordance with the present invention, depending on the sixteenth aspect, the upper device includes a master connected to the distribution line and an upper server connected to the master. The master has a function of obtaining the meter-reading data from the slave, and a function of sending the meter-reading data obtained from the slave to the upper server. The upper server is configured to store the meter-reading data received from the master.

According to the energy management system of the eighteenth aspect in accordance with the present invention, depending on the sixteenth or seventeenth aspect, the communication terminal has a function of communicating with the electric appliance.

### BRIEF DESCRIPTION OF THE DRAWINGS

FIG. 1 is a configuration diagram illustrating an energy management system of one embodiment in accordance with the present invention.

FIG. 2 is a schematic configuration diagram illustrating a primary part of the above system.

FIG. 3 is a schematic configuration diagram illustrating a primary part of the above system.

FIG. 4 is a block diagram illustrating a slave of the above energy management system.

FIG. 5 is a schematic configuration diagram illustrating a usage example of the above energy management system.

FIG. 6 is a diagram illustrating an example of a setting of initial channels relating to an example shown in FIG. 5.

FIG. 7 is an explanatory diagram illustrating an operation in a channel setting procedure in the above energy management system.

FIG. 8 is a diagram illustrating an example of a setting of channels relating to the example shown in FIG. 5.

FIG. 9 is a diagram illustrating an example of the setting of channels relating to the example shown in FIG. 5.

### DESCRIPTION OF EMBODIMENTS

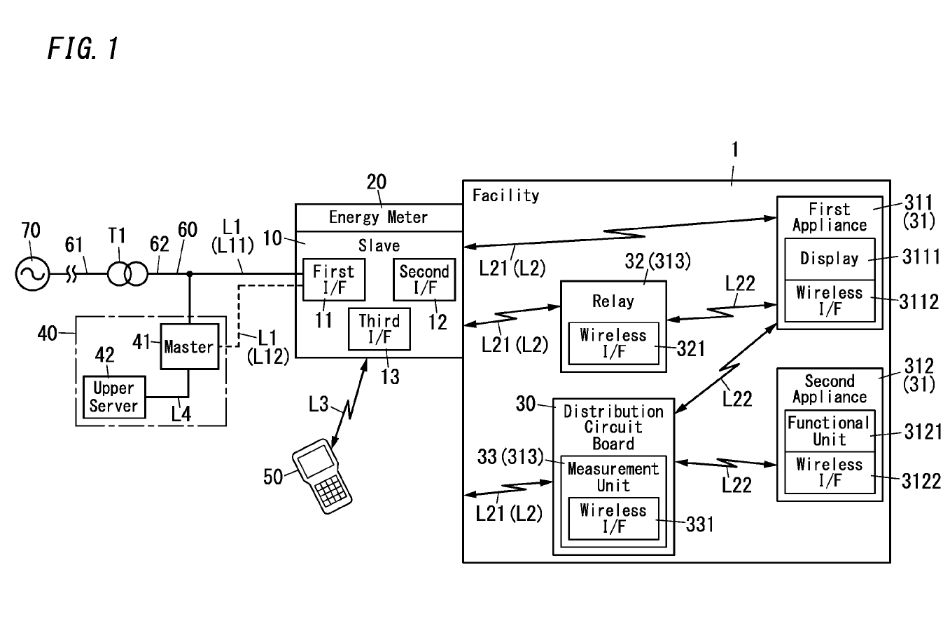

FIG. 1 shows the energy management system of the present embodiment configured to collect, from an energy meter 20 for measuring an amount of electric energy supplied to a predetermined place (in the present embodiment, a facility 1) from a power source (in the present embodiment, a commercial AC power source) 70 through a distribution line 60, meter-reading data containing the amount of electric energy. Note that, the power source 70 is not limited to a commercial AC power source. Further, the predetermined place is not limited to the facility 1.

The energy management system of the present embodiment includes a slave (communication device) 10, an upper device 40, and a communication terminal (maintenance terminal) 50.

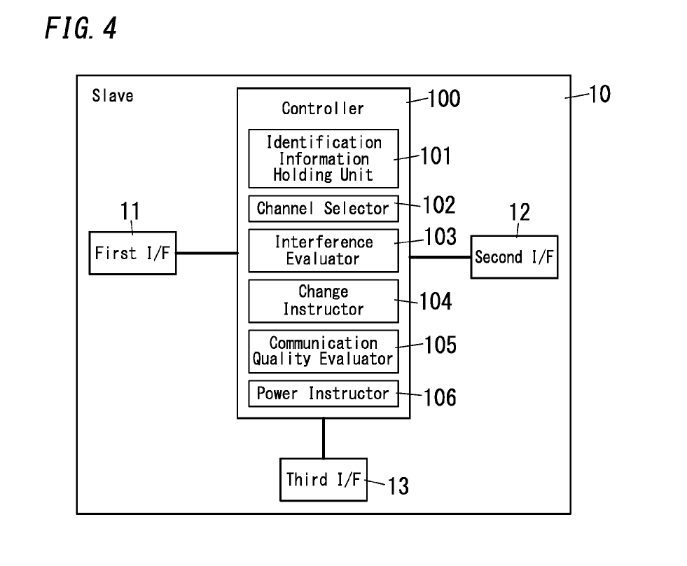

The slave 10 is configured to obtain the meter-reading data including the amount of electric energy from the energy meter 20. For example, as shown in FIG. 4, the slave 10 includes a first interface unit 11, a second interface unit 12, a third interface unit 13, a meter interface unit (not shown), and a controller 100.

The first interface unit 11 is used for communication with the upper device 40. In other words, the first interface unit 11 is configured to communicate with the upper device 40. For example, the first interface unit 11 is implemented by a combination of hardware and software necessary to communicate with the upper device 40.

The second interface unit 12 is used for communication with an electric appliance 31 installed in the predetermined place (facility 1). In other words, the second interface unit 12 is configured to communicate with the electric appliance 31. The second interface unit 12 is configured to perform wireless communication using an electric wave with the communication terminal 50. For example, the second interface unit 12 is implemented by a combination of hardware and software necessary to communicate with the electric appliance 31.

Note that, the electric appliance 31 is not necessarily fixed to the predetermined place. The electric appliance 31 may be portable and be placed on the predetermined place. In short, it is sufficient that the electric appliance 31 is available in the predetermined place.

The third interface unit 13 is used for communication with the communication terminal 50. In other words, the third interface unit 13 is configured to communicate with the communication terminal 50. The third interface unit 13 is configured to perform wireless communication using an electric wave with the communication terminal 50. For example, the third interface unit 13 is implemented by a combination of hardware and software necessary to communicate with the communication terminal 50.

The meter interface unit is used for communication with the energy meter 20. In other words, the meter interface unit is configured to communicate with the energy meter 20. For example, the meter interface unit is configured to perform near field communication using infrared as transmission medium with the energy meter 20. For example, the meter interface unit is implemented by a combination of hardware and software necessary to communicate with the energy meter 20.

The controller 100 has a function of obtaining the meter-reading data from the energy meter 20. Especially, the controller 100 communicates with the energy meter 20 through the meter interface unit to obtain the meter-reading data from the energy meter 20. Further, the controller 100 has a function of controlling the first interface unit 11 to send the meter-reading data to the upper device 40, and a function of controlling the third interface unit 13 to send the meter-reading data to the communication terminal 50.

The energy meter 20 is connected to the power source 14 through a transformer (step-down transformer) 6 configured to adjust electricity from the power source 14 to electricity appropriate to the predetermined place (facility 1). The distribution line 60 includes a distribution line (first path) 61 between the power source 14 and the transformer T1, and a distribution line (second path) 62 between the transformer T1 and the energy meter 20.

The upper device 40 is connected to the second path 62. The upper device 40 includes a master 41 connected to the distribution line 60 (the second path 62) and an upper server 42 connected to the master 41.

The master 41 has a function of obtaining the meter-reading data from the slave 10, and a function of sending the meter-reading data obtained from the slave 10 to the upper server 42.

The upper server 42 is configured to store the meter-reading data received from the master 41.

The communication terminal 50 has a function of obtaining the meter-reading data from the slave 10, and a function of communicating with the electric appliance 31.

Hereinafter, the energy management system of the present embodiment is described in more detail. As shown in FIG. 1, the energy management system described below includes the energy meter 20 configured to measure an amount of energy consumed in the facility 1 and the slave 10 attached to the energy meter 20. Note that, the phrase “the slave 10 is attached to the energy meter 20” means that the slave 10 and the energy meter 20 are installed as a single device. It is preferable that the slave 10 and the energy meter 20 are accommodated in the same casing, but the slave 10 and the energy meter 20 may be accommodated in different casings.

In the following example, the facility 1 is one of dwelling units in a condominium. However, the facility 1 is not limited to such a dwelling unit, but may be a residence, an office, or a factory.

The energy meter 20 includes an upstream side connected to the distribution line (the first path 61 and the second path 62) on a secondary side of the transformer T1, and a downstream side connected to a distribution line (not shown) to a distribution circuit board 30 installed in the facility.

The location of the transformer T1 depends on a scale of premises receiving commercial electricity. As for a detached house, the transformer T1 may be situated on a pole, on the ground, or in the ground, for example. As for a condominium, the transformer T1 is situated inside an electrical room. Electric appliances used in the facility 1 are connected to distribution lines on a downstream side of the distribution circuit board 30.

The slave 10 is placed close to the energy meter 20. For example, the slave 10 performs near field communication using infrared as a transmission medium to obtain the meter-reading data including the amount of energy measured by the energy meter 20. The slave 10 has: a function of transmitting the meter-reading data obtained from the energy meter 20 to the upper device 40; a function of communicating with the electric appliance 31 that is one of electric appliances used in the facility 1 and has a communication function; and a function of communicating with the maintenance terminal (communication terminal) 50 described in detail below.

In other words, the slave 10 communicates with a desired device through a corresponding one of three types of communication paths including a first communication path L1 to the upper device 40, a second communication path L2 to the electric appliance 31, and a third communication path L3 to the maintenance terminal 50. The detailed configuration of the slave 10 and the communication paths L1, L2, and L3 are described below. Communication between the slave 10 and the upper device 40 through the first communication path L1 is referred to as “A-route communication”, and communication between the slave 10 and the electric appliance 31 through the second communication path L2 is referred to as “B-route communication”.

The upper device 40 includes the master 41 and the upper server 42. The master 41 is placed adjacent to the transformer T1 and communicates with the slave 10 through the first communication path L1. The upper server 42 communicates with the master 41 through a transmission path L4 formed between the upper server 42 and the master 41.

The upper server 42 is a server computer configured to collect the meter-reading data from the facilities 1 in a management area. The upper server 42 may be operated by an electric power company and a service agent company that performs collection of the electric bill and aggregation of the amount of energy of the facility 1 on behalf of the electric power company.

The master 41 collects the meter-reading data of each facility 1 from the slave 10 provided to at least one facility 1 through the first communication path L1. Additionally, the master 41 transmits the meter-reading data collected from the at least one slave 10 to the upper server 42 at one time. In short, the master 41 communicates the slave 10 managed by the master 41 through the first communication path L1 and aggregates the meter-reading data of the at least one facility 1. The master 41 sends the aggregated meter-reading data to the upper server 42 at one time or divides the aggregated meter-reading data into parts and transmits the parts sequentially. The slave 10 directly communicates with the master 41 or communicates with the master 41 by use of multihop communication.

The electric appliance 31 communicating with the slave 10 includes at least one of a first appliance 311 including a display and a second appliance 312 having a function of receiving a change request of operation or settings through communication with another device. There may be a third appliance 313 interposed between the slave 10 and any of the first appliance 311 and the second appliance 312. The third appliance 313 is configured to relay communication. In short, the electric appliance 31 may be any one of the first appliance 311, the second appliance 312, a combination of the first appliance 311 and the third appliance 313, a combination of the second appliance 312 and the third appliance 313 and a combination of the first appliance 311, the second appliance 312, and the third appliance 313.

The third appliances 313 may include a relay 32 and a power measurement unit 33. The relay 32 merely relays communication between the first appliance 311 or the second appliance 312 and the slave 10. The power measurement unit 33 is attached to the distribution circuit board 30, and has a relaying function in addition to a function of measurement of power consumptions at a main circuit and a branch circuit.

The first appliance 311 includes a display 3111 configured to display various types of information, and a wireless interface unit 3112 configured to perform bidirectional wireless communication using an electric wave as a transmission medium with other devices. For example, the display 3111 displays an amount of energy obtained from the power measurement unit 33 attached to the distribution circuit board 30 or an operation condition or setting information of the second appliance 312.

Note that, it is preferable that the first appliance 311 include an operation unit for selecting information displayed by the display 3111 and providing instructions to other devices. The first appliance 311 may be a dedicated device, a set of an appropriate interface device and a television receiver, or a mobile device such as a tablet and a smartphone.

The second appliance 312 includes a functional unit 3121 configured to provide a function for a desired device, and a wireless interface unit 3122 configured to perform bidirectional wireless communication using an electric wave as a transmission medium with other devices. The second appliance 312 has a function of notifying other devices of an operation condition of the second appliance 312 through the wireless interface unit 3122 in addition to a function of receiving a request of change of an operation or settings from another device through the wireless interface unit 3122.

The relay 32 includes a wireless interface unit (hereinafter, “interface unit” is abbreviated as “I/F” if needed) 321 configured to perform bidirectional wireless communication using an electric wave as a transmission medium with the slave 10 and the first appliance 311. In other words, the relay 32 forms a communication path L21, that is the second communication path L2, between the relay 32 and the slave 10, and forms a communication path L22 between the relay 32 and the first appliance 311.

The power measurement unit 33 can measure the power consumptions at the main circuit and the branch circuit, and allow the first appliance 311 to display measurement results, and allow the second appliance 312 to operate based on the measurement results. The power measurement unit 33 may have a function of transmitting the measurement results to the upper device 40 or the communication terminal 50 through the slave 10.

The relay 32 performs bidirectional communication with the first appliance 311 through the communication path L22 in which a transmission medium is electric waves. Further, the power measurement unit 33 performs bidirectional wireless communication with at least one of the first appliance 311 and the second appliance 322 through the communication path L22 in which a transmission medium is electric waves.

As described above, each of the relay 32 and the power measurement unit 33 has a function of communicating with the slave 10. Bidirectional wireless communication using the communication path L21 in which the transmission medium is electric waves is used for communication between the slave 10 and the relay 32 as well as the power measurement unit 33. The relay 32 and the power measurement unit 33 include the wireless I/F 321 and a wireless I/F 331 to perform wireless communication with the slave 10, respectively.

The first appliance 311 may be configured to communicate with the second appliance 312, however such a configuration is not illustrated in FIG. 1. In this configuration, the first appliance 311 communicates with the slave 10 and the second appliance 312, and thus functions as a so-called HEMS (Home Energy Management System) controller.

The slave 10 includes the first I/F 11 for communicating with the upper device 40 through the first communication path L1 and the second I/F 12 for communicating with the electric appliance 31 through the second communication path L2. Additionally, the slave 10 includes the third I/F 13 for communicating with the maintenance terminal 50 through the third communication path L3, and the controller 100 configured to overall control the first I/F 11, the second I/F 12, and the third I/F 13.

Each of the first I/F 11, the second I/F 12, and the third I/F 13 sends and receives a packet including a header, a payload, and a trailer. The header includes information for identifying channels individually set to the first communication path L1, the second communication path L2, and the third communication path L3.

The slave 10 includes as hardware components a device such as a microcomputer including a processor designed to operate in accordance with programmes and a device functioning as an interface. The programmes define operations of the microcomputer to implement functions described below.

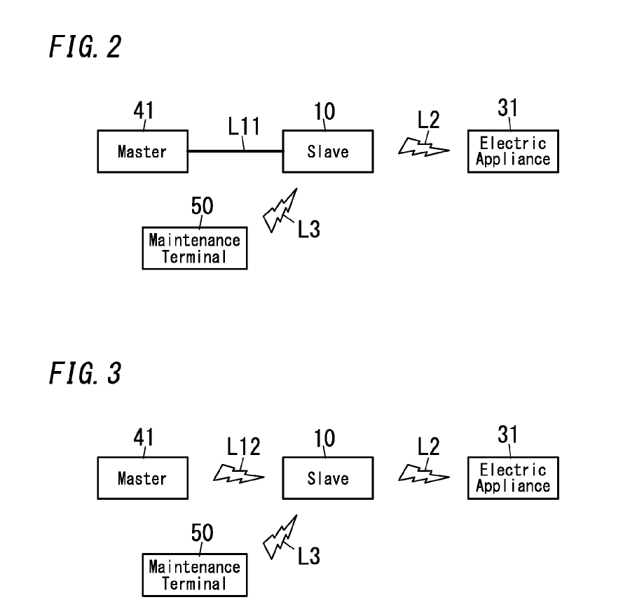

As illustrated in FIG. 2 and FIG. 3, in the present embodiment, electric waves are used as the transmission media of the second communication path L2 and the third communication path L3 for wireless communication.

The first communication path L1 is selected from the communication path L11 (see FIG. 2) in which the transmission medium is the distribution line (second path 62) on the secondary side of the transformer T1 and the communication path L12 (see FIG. 3) in which the transmission path is electric waves.

The first I/F 11 is configured in accordance with at least one of a specification suitable for the communication path L11 for the power line communication and a specification suitable for the communication path L12 for the wireless communication. In the present embodiment, the first interface unit 11 has the function of performing the power line communication with the upper device 40 through the distribution line (second path) 62 and the function of performing the wireless communication using electric waves with the upper device 40.

The maintenance terminal 50 is basically used for obtaining the meter-reading data through the slave 10. However, the maintenance terminal 50 has a function of communicating with appliances used in the facility 1. For example, the maintenance terminal 50 may change the settings of the electric appliance 31 or control the operation of the electric appliance 31 through the slave 10, by sending instructions for the electric appliance 31 to the slave 10.

Additionally, parameters set to the slave 10 may be changed by use of the maintenance terminal 50, and instructions for termination of power supply to homes can be given by use of the maintenance terminal 50. The parameters of the slave 10 may include a time interval of obtaining the meter-reading data, transmission power and receiving sensitivity for wireless communication, a modulation scheme, and a frequency, for example.

For example, wireless communication can be performed according to a specification of specified low power radio stations with 920 MHz band and transmission power equal to or less than 20 mW, but other schemes such as Wi-Fi (registered trademark), ZigBee (registered trademark), and Bluetooth (registered trademark) can be used.

The present embodiment is characterized in that wireless communication schemes (e.g., frequencies, modulation schemes, and time slots) used for the second communication path L2 and the third communication path L3 are different from each other. A channel allocated to the communication path is defined by a frequency for transmitting information. A time slot is a time period obtained by dividing a communication period, and such a time slot also can be used as the channel for communication. In summary, the channel may be defined by a frequency, a time slot, or a combination of a frequency and a time slot.

When different channels are allocated to individual communication paths, information can be transmitted without causing interference between the different communication paths.

Although the transmission media of the second communication path L2 and the third communication path L3 are electric waves, different schemes (wireless communication schemes) are used for the second communication path L2 and the third communication path L3 to form communication paths independent from each other. The phrase “communication paths independent from each other” means communication paths in which interference between electric waves of the second interface unit 12 and the third interface unit 13 does not occur. Note that the phrase “interference does not occur” is intended to be interpreted as that interference does not occur in a strict sense, or that interference does not occur substantially.

Consequently, information transmitted through the second communication path L2 does not interfere with information transmitted through the third communication path L3. In other words, the communication between the slave 10 and the maintenance terminal 50 does not interfere with the communication between the slave 10 and the electric appliance 31.

Further the communication through the second communication path L2 and the communication through the third communication path L3 do not interfere, and therefore it is easy to keep desired communication speeds. Note that, in a case where different modulation schemes are used for the different communication paths, interference may occur when the same channel is used for the communication paths. However, when the modulation schemes are different, there may be differences between transmission speeds and communication qualities, and thus a possibility of avoiding interference is high.

Note that, when the transmission medium of the first communication path L1 is electric waves, in some cases the first communication path L1 is allowed to share the same path with the second communication path L2 or the third communication path L3. In other words, the first interface unit 11 may be configured to perform wireless communication in a scheme same as the scheme of the second interface unit 12, or may be configured to perform wireless communication in a scheme same as the scheme of the third interface unit 13.

In the former case, the first interface unit 11 and the second interface unit 12 perform the wireless communication in the same scheme. In other words, the first communication path L1 and the second communication path L2 share the same communication path, and therefore the first I/F 11 and the second I/F 12 can be implemented by the same unit. In the latter case, the first interface unit 11 and the third interface unit 13 perform the wireless communication in the same scheme. The third communication path L3 and the second communication path L2 are independent communication paths, but the third communication path L3 and the first communication path L1 share the same communication path. Hence the third I/F 13 and the first I/F 11 can be implemented by the same unit. Consequently, in any case, the structure of the slave 10 can be simplified.

Note that, when a plurality of communication paths for wireless communication are made independent from each other, it is preferable that to improve independence of the communication paths a type, a direction, polarization of an antenna can be changed in addition to frequencies, modulation schemes, time slots, transmission power, and receiving sensitivity, for each communication path. In short, the wireless communication scheme is a protocol defining rules such as frequencies, modulation schemes, time slots, transmission power of electric waves, receiving sensitivity for electric waves, and alignment of antennas.

In other words, the second interface unit 12 is configured to perform the wireless communication in a protocol different from a protocol used by the third interface unit 13. For example, the protocol of the second interface unit 12 is determined to define channels that do not cause interference between electric waves of the second interface unit 12 and the third interface unit 13 for any channel defined by the protocol of the third interface unit 13.

In the aforementioned configuration, the maintenance terminal 50 is added, and thus use of the maintenance terminal 50 allows collection of the meter-reading data of each facility 1 even when the communication between the slave 10 and the upper device 40 fails.

In a case where the distribution line on the secondary side of the transformer T1 and on the upstream side of the energy meter 20 is used as the first communication path L1 and the power line communication is performed between the slave 10 and the master 41, there is no need to form an additional communication path, and thus installation of the slave 10 is facilitated. In contrast, in a case where electric wave are used as the transmission medium defining the first communication path L1, the communication between the slave 10 and the master 41 is enabled irrespective of the distribution line.

As illustrated in FIG. 2 and FIG. 3, the transmission media of the communication between the slave 10 and the electric appliance 31 as well as the maintenance terminal 50 are electric waves, and therefore particular work is unnecessary for installing the slave 10 in the facility. By simply attaching the slave 10 to the energy meter 20, it is possible to construct a so-called smart meter including a communication function with the upper device 40 and a further communication function with the electric appliance 31. Work of installing the slave 10 is easy, and hence it is easy to construct the smart meter. In short, the smart meter is constituted by the energy meter 20 and the slave (communication device) 10.

As described above, the smart meter can be constructed by attaching the slave 10, and it is easy to change the specification of the slave 10. Thus, it is possible to ensure extendability of functions. For example, a function for acting as a component of an energy management system can be added to the slave 10 in addition to the function of obtaining the meter-reading data, if necessary. In this case, the slave 10 can be used for suppressing the power consumption of the electric appliance 31 used in the facility 1.

The slave 10 can communicate with the maintenance terminal 50, and the maintenance terminal 50 can not only obtain the meter-reading data but also change the parameters of the slave 10 and give instructions to the electric appliance 31. The parameters of the slave 10 can be changed by use of the maintenance terminal 50, and hence it is possible to adjust the parameters so that the communication is optimized in accordance with environments of a site where the slave 10 is installed. Moreover, the communication terminal 50 can provide instructions to the electric appliance 31 used in the facility 1, and therefore it is possible to make adjustment for enabling appropriate communication according to the site.

In order to allow the upper device 40 to identify one or more slaves 10, it is necessary that identification information is allocated to individual slaves 10. For example, such identification information is selected from an address used by the slave 10 to communicate with the upper device 40, a product number uniquely given to the slave 10, and a MAC address given to the slave 10 with a communication function, for example. It is sufficient that the identification information is uniquely allocated to the slave 10 managed by the upper device 40. In summary, it is sufficient that the identification information is unique with regard to the slaves 10 managed by the master 41. As shown in FIG. 4, the controller 100 of the slave 10 includes an identification information holding unit 101 for holding the identification information. In other words, the controller 100 includes the identification information holding unit 101 storing the identification information unique to the slave 10. For example, the controller 100 is configured to, when receiving the identification information from the upper device 40, store the received identification information in the identification information holding unit 101.

The following explanation is made to an example in which the master 41 issues an address for communication allocated to the slave 10 managed by the master 41 and this address is used as the identification information.

Accordingly, the address used by the slave 10 in the A-route communication is issued by the master 41. In this example, the master 41 issues the address in response to reception of an address request from the slave 10, and sends the issued address to the slave 10 that has sent the address request. Additionally, the master 41 issues the addresses for the slaves 10 in an order of reception of the address request. The address is an integer indicative of a number of issuance.

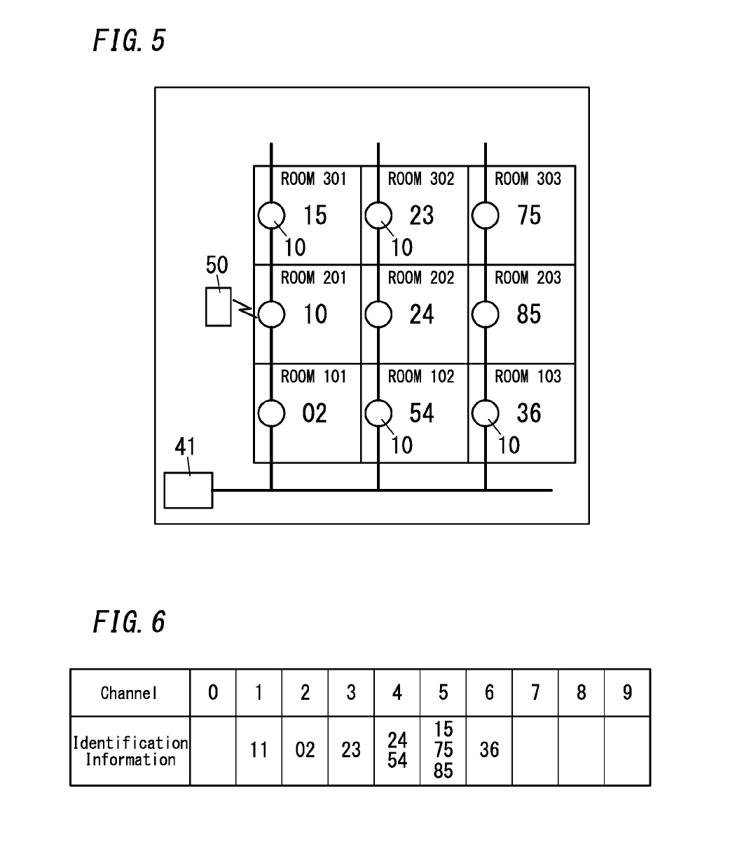

FIG. 5 shows an example in which the slaves 10 are individually situated in dwelling units of a condominium, and numbers placed on right sides of the slaves 10 represent the addresses issued by the master 41. Squares illustrated in FIG. 5 schematically represent the dwelling units, and labels “room—” represent dwelling unit number. In this example, the single master 41 is installed in the condominium, and collects the meter-reading data from the slaves 10 individually installed in the dwelling units of the condominium.

As described above, the master 41 allocates the addresses to the slaves 10 in the order of reception of the address requests. As illustrated in FIG. 5, there is no relation between a physical location of the dwelling unit represented by the dwelling unit number and the address of the slave 10. As described above, if no relation between the address and the dwelling unit number is required, a procedure of allocating the addresses to the slaves 10 is facilitated and thus it can be easy to install the system.

In this regard, a communication area of the slave 10 must be limited so that the slave 10 is allowed to communicate with the electric appliance 31 in the facility associated with the slave 10 and is not allowed to communicate with the electric appliance 31 in a neighboring facility. Further, an area in which the slave 10 and the maintenance terminal 50 communicate with each other must be limited so that, in a period in which the slave 10 communicates with the maintenance terminal 50, the maintenance terminal 50 is not allowed to communicate with another slave 10. Well known techniques of limiting communication areas may include a technique of selecting channels used in communication areas, a technique of adjusting either the output power at the transmission side or the reception sensitivity at the reception side, and a technique of distributing encryption keys used in communication areas.

The limitation of the communication area may be required for not only a case in which the second I/F 12 and the third I/F 13 use electric waves as the transmission media but also the power line communication using the distribution line as the transmission medium. In the following, the technique of selecting channels is described, and after that the technique of adjusting either the output power or the reception sensitivity is described.

The slave 10 selects channels used in the second I/F 12 and the third I/F 13 from a plurality of channels in a predetermined selectable range. Note that, normally, the third I/F 13 is not used. In view of this, it is preferable that the third I/Fs 13 of all the slaves 10 use the same channel and this channel be used by the second I/F 12 while the third I/F 13 is not used.

The channel is defined by at least one of a frequency and a time slot. With regard to the slave 10, channels to be used by the second I/F 12 and the third I/F 13 of the slave 10 are defined by parameters in the selectable range selected from various types of frequencies, various types of time slots, or combinations of various types of frequencies and various types of time slots. The slave 10 includes a channel selector 102 configured to select a channel used by the slave 10 from the plurality of channels in the predetermined selectable range.

In summary, as shown in FIG. 4, the controller 100 of the slave 10 includes the channel selector 102 configured to select a communication channel (first communication channel) to be used for wireless communication by the third interface unit 13 from the plurality of channels. Additionally, the channel selector 102 is configured to designate a communication channel (second communication channel) to be used for the wireless communication by the second interface unit 12. In the present embodiment, the channel selector 102 selects the same channel, as the first communication channel and the second communication channel.

It is sufficient that the channel selector 102 is configured to select from a plurality of channels a communication channel used in the wireless communication of at least one of the second interface unit 12 and the third interface unit 13.

Note that, the channel selector 102 may be configured to select communication channel (third communication channel) used in the wireless communication of the first interface unit 11 from a plurality of channels.

Integers more than 0 associated with the parameters in the aforementioned selectable range are used as the channels in the present embodiment. There is no intent to limit the format for representing the channels. However, using integers allows easy designation of the channels.

Before fixing the channel to be used, the slave 10 performs a prior process of tentatively setting the channel, and performs a subsequent process of, after evaluating interference in a case where the communication is performed by use of the channel set in the prior process, changing the channel based on the evaluation result if necessary. In summary, the slave 10 performs two processes including the prior process and the subsequent process. In the prior process, the channel (hereinafter referred to as “initial channel”) is tentatively set, and in the subsequent process, the initial channel is changed appropriately to avoid occurrence of interference.

The slave 10 includes an interference evaluator 103 configured to evaluate a degree of interference in a case where the initial channel tentatively set is used, and a change instructor 104 configured to instruct the channel selector 102 to change the channel when there is a possibility of interference. In short, as shown in FIG. 4, the controller 100 of the slave 10 includes the interference evaluator 103 and the change instructor 104.

The interference evaluator 103 is configured to judge whether interference of electric waves occurs in the communication channel (e.g., the first communication channel, the second communication channel, and the third communication channel). For example, the interference evaluator 103 calculates an evaluation value representing a degree of interference, and evaluates the degree of interference through comparison of the evaluation value with a prescribed threshold.

For the evaluation value for evaluating the degree of interference, a received signal strength indication (RSSI), the frequency, the time slot, or an appropriate combination of these can be used, for example. When the received signal strength indication is high, interference is likely to occur. Additionally, when a difference between the frequencies is small or when the time slots are adjacent to each other, interference also is likely to occur. Hence, by converting such information into numerical values as the evaluation values, indications for evaluating the degree of interference can be obtained.

It is assumed that the evaluation value is determined so as to be monotonically increased with a change in the degree of interference. In this case, the interference evaluator 103 compares the evaluation value with the threshold. When the evaluation value exceeds the threshold, the interference evaluator 103 determines that the degree of interference is high and there is need to change the channel.

The change instructor 104 is configured to provide the change instruction to the channel selector 102 when the interference evaluator 103 determines that the interference occurs. For example, when the interference evaluator 103 determines that the change of the channel is necessary (i.e., the evaluation value exceeds the threshold), the change instructor 104 instructs the channel selector 102 to change the selected channel. Additionally, the change instructor 104 is configured to not provide the change instruction to the channel selector 102 when the interference evaluator 103 determines that the interference does not occur. For example, when the evaluation value is less than the threshold in the interference evaluator 103, the change instructor 104 uses the channel selected by the channel selector 102 for communication.

The channel selector 102 is configured to change the communication channel in response to reception of the change instruction from the change instructor 104.

In particular, the channel selector 102 is configured to select from the plurality of channels the initial channel as a candidate for the communication channel, depending on the identification information stored in the identification information holding unit 101. The channel selector 102 is configured to, when receiving the change instruction from the change instructor 104, select from the plurality of channels a channel different from the initial channel, and set the selected channel as the communication channel. The channel selector 102 is configured to, when not receiving the change instruction from the change instructor 104, set the initial channel as the communication channel.

In the following, a concrete example of the operation of the slave 10 is described using the case shown in FIG. 5. This example of the operation is only an example, and there is no intent to limit the operation of the slave 10, and therefore the slave 10 may perform other alternative operation.

The illustrated instance shows a condition in which the master 41 issues the identification information for the slave 10 in response to the address request from the slave 10. The slave 10 holds the identification information issued by the master 41 in the identification information holding unit 101. In this operation example, the channel selector 102 selects as the initial channel the channel corresponding to the least significant digit of an integer of two digits held in the identification information holding unit 101. In the illustrated instance, the identification information issued under management of the master 41 is of two digits such as “02”, “54”, . . . , “15”, and “23”. The master 41 issues the identification information so as not to be same as the identification information that has already been issued, and therefore the same identification information is not issued under the management area of the master 41.

The channel selector 102 of the slave 10 uses the channel corresponding to the least significant digit of the identification information as the initial channel, and therefore the channel corresponding to a number of one digit, that is, “0” to “9” is set to the initial channel as shown in FIG. 6. In the case of the instance illustrated in FIG. 5, the same initial channel “04” is given to the room 102 and the room 202 adjacent in the vertical direction, and the same initial channel “05” is given to the room 203 and the room 303 adjacent in the vertical direction.

Note that, the initial channel is selected by use of the least significant digit of the identification information defined by an integer, buy may be selected by use of another rule. For example, the initial channel may be selected by use of a remainder of division of the identification information defined by an integer by an appropriate divider. When the initial channel is selected based on the least significant digit, the number of selectable channels is 10. Whereas, when the initial channel is selected based on the remainder, the number of selectable channels depends on the value of the divider.

As described, there is no relation between the position of the dwelling unit and the identification information of the slave 10. Therefore, when the channel is selected based on the least significant digit of the identification information, the same channel is set to the slaves 10 installed in the neighboring dwelling units in some cases. Hence, there is a possibility that the same initial channel is set to the adjacent slaves 10. When the slaves 10 using the same initial channel are installed adjacent to each other, interference is likely to occur in communication.

The slave 10 measures the received signal strength indications of all the channels in the selectable range in order to detect the initial channel set to another slave 10 existing in an area in which the slave 10 can communicate. And, the slave 10 records as “in-use channel” a channel corresponding to the received signal strength indication greater than a prescribed threshold. The process of detecting the in-use channel is performed by the interference evaluator 103. To detect the in-use channel, it is necessary to measure the received signal strength indication for each channel. Hence, the interference evaluator 103 sequentially in turn measures the received signal strength indications of all the channels in the selectable range.

When the in-use channel is same as the channel to be used, interference is likely to occur. Hence, the interference evaluator 103 of the slave 10 tries to detect another slave 10 which uses a channel that is one of the detected in-use channels and is same as the initial channel of the slave 10. In a process of measuring the received signal strength indications of the individual channels, the slave 10 receives the identification information as well as the channel of another slave 10. For example, the interference evaluator 103 of the slave 10 receives packets outputted from the other slaves 10 to evaluate the received signal strength indications, and extracts the identification information of another slave 10 from the header of the received packet. Consequently, the slave 10 obtains the identification information of another slave 10 that has the same initial channel as the slave 10 and gives the received signal strength indication greater than the threshold.

In the example described herein, the identification information of the slave 10 is an integer. When the same initial channel is set to the two or more slaves 10, the interference evaluator 103 selects one slave 10 that is allowed to use this initial channel from the two or more slaves 10 based on whether the identification information is greater. When two or more other slaves 10 have the same initial channel and give the received signal strength indications greater than the threshold, the interference evaluator 103 determines whether the identification information is greater than the other identification information. When the identification information of the slave 10 is the smallest of the pieces of the identification information of the other slaves 10, the interference evaluator 103 of the slave 10 allows the slave 10 to continue to use this initial channel as the communication channel. Further, the interference evaluator 103 of the slave 10 requests the channel selector 102 to change the channel by use of the change instructor 104 when the identification information of the slave 10 is not the smallest of the pieces of the identification information of the other slaves 10.

When the interference evaluator 103 intends to request the change instructor 104 to change the channel, first the interference evaluator 103 tries to detect the channel corresponding to the received signal strength indication equal to or less than the judgment threshold from the channels in the selectable range. When the received signal strength indication of the channel is equal to or less than the judgment threshold, it can be considered that the channel is not used or interference is unlikely to occur even when the channel is used. Hence, the detected channel is treated as “available channel”. When the available channel is detected, the interference evaluator 103 provides information of the available channel to the change instructor 104. In summary, the interference evaluator 103 is configured to judge whether the plurality of channels includes at least one available channel that does not cause interference of the electric wave. The interference evaluator 103 is configured to, when determining that the plurality of channels includes the available channel, provide available channel information identifying the at least one available channel to the change instructor 104. Note that, in some cases, there is a plurality of available channels. In such cases, the available channel information individually identifies the plurality of available channels.

The change instructor 104 is configured to select a designated available channel to be set as the communication channel (e.g., the first communication channel, the second communication channel, and the third communication channel) from the at least one available channel identified by the available channel information, and provide the change instruction indicating the designated available channel to the channel selector 102. For example, the change instructor 104 instructs the channel selector 102 to change the channel after a lapse of a waiting time period determined based on the initial channel. The waiting time period is determined so that the waiting time period is shorter as the number of the initial channel is smaller (e.g., the waiting time period is given by multiplying a unit time period by the number of the initial channel). When the waiting time period is determined in such a manner, it is possible to avoid an undesired situation in which the slaves 10 selecting the different initial channels select the same available channel.

The channel selector 102 is configured to, when receiving the change instruction from the change instructor 104, set the designated available channel indicated by the change instruction as the communication channel.

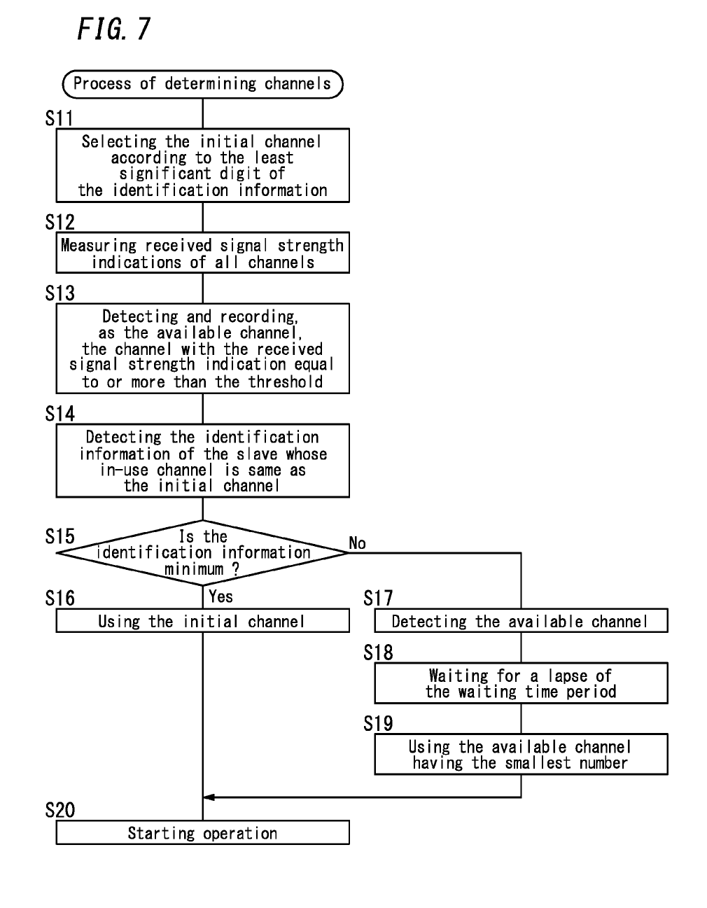

The aforementioned channel selection techniques are collectively illustrated in FIG. 7. In preprocessing, the channel selector 102 of the slave 10 in question selects the initial channel corresponding to the least significant digit of the identification information of the slave 10 in question defined by an integer (S11). Thereafter, the interference evaluator 103 of the slave 10 in question measures the received signal strength indications of all the channels in the selectable range sequentially in turn (S12), detects the channel whose received signal strength indication is greater than the threshold, as the in-use channel, and records the detected channel (S13). Next, the interference evaluator 103 of the slave 10 in question obtains, from the header of the packet, the identification information of another slave 10 whose in-use channel is same as the initial channel of the slave 10 in question (S14). When another slave 10 whose in-use channel is same as the initial channel of the slave 10 in question is present and interference is likely to be caused by the presence of this slave 10, whether the identification information of this slave 10 is greater than the identification information of the slave 10 in question is determined (S15).

When the identification information of the slave 10 is minimum (S15: Yes), use of the initial channel is continued (S16). In contrast, when the identification information of the slave 10 is not minimum (S15: No), the interference evaluator 103 evaluates the received signal strength indications for all the channels to detect the available channel (S17). When the available channels are detected, after a lapse of the predetermined waiting time period (S18), the change instructor 104 instructs the channel selector 102 to select, as the channel to be used by the second I/F 12, the available channel corresponding to the smallest one of the numbers of the detected available channels (S19). Through the aforementioned manner, the channel to be used by the second I/F 12 is selected by the channel selector 102, and consequently the slave 10 starts to operate by use of the selected channel (S20).

Even when the same initial channel is set to two or more slaves 10, the fact that the same initial channel is set cannot be detected, provided that the header of the packet outputted from any of these slaves 10 cannot be received by another slave 10. When physical distances between the slaves 10 are relatively long, or there may be partitions between the slaves 10, the received signal strength indication may be so low that the slaves 10 cannot recognize the header of the packet from the others. In this case, the comparison of the identification information of the slave 10 is not performed even when interference is likely to occur.

In other words, even when the same initial channel is set to two or more slaves 10, provided that the slave 10 can communicate with the electric appliance 31 in the facility associated with the slave 10 and the maintenance terminal 50 but cannot communicate with the other slaves 10, the slave 10 can use the initial channel without change.

In view of this, the controller 100 of the slave 10 includes a communication quality evaluator 105 configured to evaluate a communication quality through test communication, and a power instructor 106 configured to adjust the output power of the second I/F 12 and the output power of the third I/F 13.

The communication quality evaluator 105 is configured to evaluate a communication quality of the communication channel (first communication channel) selected by the channel selector 102. For example, the communication quality evaluator 105 is configured to conduct test communication by use of the communication channel (first communication channel) selected by the channel selector 102 to evaluate the communication quality (communication quality of the first communication channel) of the communication path L3 between the slave 10 and the communication terminal 50.

The power instructor 106 is configured to set an intensity of an electric wave allocated to the communication channel (first communication channel) to a lower limit of a range of intensities allowing the communication quality evaluated by the communication quality evaluator 105 to satisfy a predetermined condition. For example, the power instructor 106 is configured to decrease the intensity of the electric wave (electric wave according to the communication channel) outputted from the third interface unit 13 within a range in which the communication quality (communication quality of the communication path L3) evaluated by the communication quality evaluator 105 fulfills the predetermined condition.

Further, the communication quality evaluator 105 is configured to evaluate a communication quality of the communication channel (second communication channel) selected by the channel selector 102. For example, the communication quality evaluator 105 is configured to conduct test communication by use of the communication channel (second communication channel) selected by the channel selector 102 to evaluate the communication quality (communication quality of the second communication channel) of the communication path L2 between the slave 10 and the electric appliance 31.

In this case, the power instructor 106 is configured to set an intensity of an electric wave allocated to the second communication channel to a lower limit of a range of intensities allowing the communication quality (communication quality of the second communication channel) evaluated by the communication quality evaluator 105 to satisfy a predetermined condition. For example, the power instructor 106 is configured to decrease the intensity of the electric wave (electric wave according to the second communication channel) outputted from the second interface unit 12 within a range in which the communication quality (communication quality of the communication path L2) evaluated by the communication quality evaluator 105 fulfills the predetermined condition.

Additionally, the communication quality evaluator 105 is configured to evaluate a communication quality of the communication channel (third communication channel) selected by the channel selector 102. For example, the communication quality evaluator 105 is configured to conduct test communication by use of the communication channel (third communication channel) selected by the channel selector 102 to evaluate the communication quality (communication quality of the third communication channel) of the communication path L1 (L12) between the slave 10 and the upper device 40.

In this case, the power instructor 106 is configured to set an intensity of an electric wave allocated to the third communication channel to a lower limit of a range of intensities allowing the communication quality (communication quality of the third communication channel) evaluated by the communication quality evaluator 105 to satisfy a predetermined condition. For example, the power instructor 106 is configured to decrease the intensity of the electric wave (electric wave according to the third communication channel) outputted from the first interface unit 11 within a range in which the communication quality (communication quality of the communication path L12) evaluated by the communication quality evaluator 105 fulfills the predetermined condition.

After the slave 10 obtains the address for communication issued by the master 41 and the initial channel is set, the slave 10 first performs test communication with the electric appliance 31 in the facility managed by the slave 10 and test communication with the maintenance terminal 50. Note that, in a process of setting the initial channel to the slave 10, it is assumed that a person who installs the slave 10 carries the maintenance terminal 50 and thus the maintenance terminal 50 is present in the communication area of the slave 10.

The slave 10 conducting the test communication decreases the output power for transmitting packets with time, and obtains communication statistic information (communication quality) such as a communication error rate and a retransmission rate. Additionally, this slave 10 decreases the output power down to an allowable lower limit of the range in which the communication qualities with the electric appliance 31 and the maintenance terminal 50 are kept good. As described above, the output power of the slave 10 is decreased down to the allowable lower limit, and thus interference can be avoided even when the same initial channel is set to a plurality of slaves 10. Moreover, the slave 10 decreases the output power down to the allowable limit within the range in which the communication quality is kept good, and therefore the communication quality with the electric appliance 31 in the facility associated with the slave and the communication quality with the maintenance terminal 50 can be maintained. As a result, a probability that the slave 10 changes the initial channel is reduced, although the number of selectable channels is limited, the channels can be set so as to avoid interference even when the number of slaves 10 is greater than the number of channels.

To enable communication between the slave 10 and the electric appliance 31 in the facility associated with the slave 10, association (channel setting) between the slave 10 and the electric appliance 31 is necessary. The electric appliance 31 includes two operation modes of a registration mode in which the channel is set to associate the electric appliance 31 with the slave 10, and a normal mode in which the electric appliance 31 operates by use of the set channel. For example, in the registration mode, the electric appliance 31 selects all the channels sequentially in turn until the electric appliance 31 receives the packet sent periodically from the slave 10.

In one example, the packet sent from the slave 10 includes information for identifying the energy meter 20, and a worker inputs the information for identifying the distribution circuit board 30 into the electric appliance 31. In this example, the electric appliance 31 compares the information for identifying the energy meter 20 to select the channel of the slave 10 of the facility in which the electric appliance 31 is installed. Hence, the association between the slave 10 and the electric appliance 31 can be completed successfully. In the registration mode, the electric appliance 31 receives packets of all the channels, and therefore the electric appliance 31 may receive the packet from the slave 10 in another facility. However, use of the information for identifying the energy meter 20 can prevent association of the electric appliance 31 with the slave 10 in another facility. When the selection of the channel ends, the electric appliance 31 starts the normal mode and begins to communicate with the slave 10 by use of the selected channel.

In contrast, for example, the maintenance terminal 50 is used by a meter reader who visits for meter-reading. In this time, the maintenance terminal 50 communicates with the slave 10 to obtain the meter-reading data including an integral value of energy, and the like. Therefore, the channel setting between the slave 10 and the maintenance terminal 50 is necessary in addition to the channel setting between the slave 10 and the electric appliance 31.

The channel used by the maintenance terminal 50 is fixed. Hence, if the slave 10 is prohibited to use the channel allocated to the maintenance terminal 50, the selectable range of channels for the slave 10 is narrowed. In view of an efficiency of use of the channels, it is not preferable that the number of selectable channels be limited and nevertheless one channel be exclusively allocated to the maintenance terminal 50 that is not used frequently.

For this reason, the slave 10 of the present embodiment is configured to use the channel allocated to the maintenance terminal 50 for communication with the electric appliance 31 in a time period in which the third I/F 13 does not communicate with the maintenance terminal 50. When acknowledging the start of use of the maintenance terminal 50, the slave 10 that selects the channel to be used by the maintenance terminal 50 allows the maintenance terminal 50 to use the channel, selects another channel, and uses the selected channel.

The start of use of the maintenance terminal 50 can be acknowledged by receiving an electric wave sent from the maintenance terminal 50 when the meter reader starts to operate the maintenance terminal 50 in a vicinity of the slave 10. The maintenance terminal 50 is used in the vicinity of the slave 10, and thus the slave 10 can receive an electric wave having a relatively high electrical field intensity. Hence, the slave 10 can acknowledge the start of use of the maintenance terminal 50 by evaluating the electric field intensity of the electric wave received by the third I/F 13. The maintenance terminal 50 may send a packet for an entry request to the slave 10 at the start of use so that the slave 10 receives the address of the maintenance terminal 50 included in the header of this packet.

As for the slave 10 that selects the channel to be used by the maintenance terminal 50, when the third I/F 13 acknowledges the start of use of the maintenance terminal 50, the change instructor 104 instructs the channel selector 102 to select all the channels sequentially in turn.

In the present embodiment, the third interface unit 13 is configured to judge whether use of the communication terminal (maintenance terminal) 50 is started. The change instructor 104 is configured to, when the third interface unit 13 determines that use of the communication terminal 50 is started, provide the change instruction that indicates, as the second communication channel, a channel that does not cause interference with a channel used by the communication terminal 50. The channel selector 102 is configured to, when receiving the change instruction from the change instructor 104, change the second communication channel to the channel indicated by the change instructor 104.

Note that, the change instructor 104 may be configured to, when the third interface unit 13 determines that use of the communication terminal 50 is started, provide the change instruction that indicates, as the third communication channel, a channel that does not cause interference with a channel used by the communication terminal 50. The channel selector 102 is configured to, when receiving the change instruction from the change instructor 104, change the third communication channel to the channel indicated by the change instructor 104.

Additionally, the interference evaluator 103 monitors the received signal strength indications of the individual channels in a period in which the change instructor 104 selects the channels sequentially in turn. The slave 10 detects the channel giving the received signal strength indication equal to or less than the threshold (reference value) as the available channel, and assigns the available channel as the channel used by the second I/F 12.

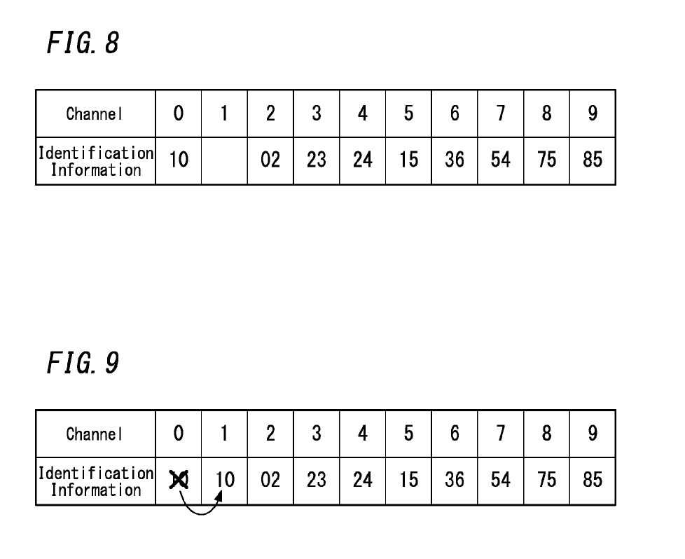

For example, it is assumed that the maintenance terminal 50 uses the channel “0”. In this example, as shown in FIG. 8, when the identification information of the slave 10 of the room 201 is “10”, the least significant digit of this identification information is “0”. When the channel is selected in accordance with the aforementioned rule, the channel used by the second I/F 12 of the slave 10 is also the channel designated by “0”. As a result, the slave 10 of the room 201 uses the channel same as the channel used by the maintenance terminal 50, for communication with the electric appliance 31.

In the allocation instance shown in FIG. 5, the channel “1” is not used by any slave 10, and it is assumed that the received signal strength indications of the channels used in the rooms 103, 203, and 303 at the slave 10 of the room 201 are too low to cause interference. When the channels are allocated to the individual slaves 10 as shown in FIG. 8, the available channels detected by the slave 10 of the room 201 are the four channels “1”, “6”, “8”, and “9”.

When the third I/F 13 of the slave 10 of the room 201 acknowledges the start of use of the maintenance terminal 50, the change instructor 104 of this slave 10 assigns a right of using the channel “0” currently assigned to the second I/F 12 to the maintenance terminal 50, and searches the available channels for the channel for communication with the electric appliance 31.

The available channels of the slave 10 are the four channels “1”, “6”, “8”, and “9”. In the case of using the rule that the channel with the smallest number of the numbers of the available channels is selected, the slave 10 selects the channel “1” as the channel (second communication channel) for communication with the electric appliance 31 as shown in FIG. 9. The rule for the slave 10 to select the channel may be appropriately determined, and for example the slave 10 can select another available channel.

The slave 10 changes the channel for communication with the electric appliance 31, and hence the slave 10 sends a preliminary notice to the electric appliance 31 before changing the channel, to instruct the electric appliance 31 to also change the channel. Note that, the association between the electric appliance 31 and the slave 10 is necessary. For this reason, the information for identifying the energy meter 20 is included in the packet sent from the slave 10 to the electric appliance 31 to give an instruction of change of the channel, and thus the electric appliance 31 can confirm that the slave 10 is a communication partner.

The slave 10 selects the pre-change channel as the channel to be used, after a lapse of a prescribed time period from the end of communication with the maintenance terminal 50. Further, before selecting the pre-change channel, the slave 10 provides a preliminary notice regarding the change of the channel to the electric appliance 31. As described above, the slave 10 that normally uses the same channel as the maintenance terminal 50 changes temporarily the normally used channel to communicate with the maintenance terminal 50. The process allows the slave 10 to normally use the channel same as the channel used by the maintenance terminal 50, and thus the efficiency of use of channels of the slave 10 can be improved.

Moreover, it is desirable that the slave 10 instruct the electric appliance 31 in the facility associated with the slave 10 and the maintenance terminal 50 carried by the person who installs the slave 10, to perform test communication similar to the test communication performed by the slave 10. While the electric appliance 31 and the maintenance terminal 50 perform the test communication, the communication quality evaluator 105 of the slave 10 giving the instruction of the test communication monitors the received signal strength indications relating to the electric appliance 31 and the maintenance terminal 50, and obtains the communication qualities from the electric appliance 31 and the maintenance terminal 50. For example, the communication quality is communication statistic information such as a communication error rate and a retransmission rate.

The communication quality evaluator 105 of the slave 10 makes evaluation by comparing at least one of the received signal strength indication and the communication quality with a threshold, and accordingly instructs the electric appliance 31 and the maintenance terminal 50 to reduce the output power to the allowable lower limit. In this manner, when the slave 10 sets the channel, the transmission power of each of the electric appliance 31 and the maintenance terminal 50 is reduced to an allowable lower limit. Therefore, the possibility that the electric appliance 31 in one facility and the maintenance terminal 50 are associated with the slave 10 of another facility is reduced. Consequently, it is possible to avoid occurrence of interference of the electric appliance 31 of one facility and the maintenance terminal 50 with the slave 10 of another facility.

As described above, the slave 10 of the energy management system of the present embodiment is a slave of an energy management system, which is attached to the energy meter 20 for measuring the energy consumed in the facility 1 and has a function of transmitting to the upper device 40 the meter-reading data including an amount of the energy measured by the energy meter 20. The slave 10 includes the first interface unit 11, the second interface unit 12, and the third interface unit 13. The first interface unit 11 is configured to communicate with the master 41 through the first communication path L1. The second interface unit 12 is configured to perform wireless communication with the electric appliance 31, that is one of electric appliances used in the facility 1 and has the communication function, through the second communication path L2 in which electric waves are used as the transmission medium. The third interface unit 13 is configured to perform wireless communication with the maintenance terminal 50 having at least a function of obtaining the meter-reading data through the third communication path L3 in which electric waves are used as the transmission medium. The second interface unit 12 and the third interface unit 13 are configured to perform communication in different schemes (wireless communication schemes) so that the second communication path L2 and the third communication path L3 are communication paths independent from each other.

Further, in the slave 10 of the energy management system of the present embodiment, the first interface unit 11 uses, as the transmission medium of the first communication path L1, the distribution line 60 on the upstream side of the energy meter 20, to perform the power line communication with the upper device 40. In this case, in the slave 10 of the energy management system of the present embodiment, the first communication path L1 is defined by the distribution line 60 (second path 62) that is on the secondary side of the transformer T1 for transmitting commercial power to the facility 1 and is on the upstream side of the energy meter 20.

Moreover, in the slave 10 of the energy management system of the present embodiment, the first interface unit 11 uses electric waves as the transmission medium of the first communication path L1 to perform wireless communication with the upper device 40. In this case, the first interface unit 11 and the third interface unit 13 may perform communication in the same scheme so that the first communication path L1 and the third communication path L3 are the same communication path. Alternatively, the first interface unit 11 and the second interface unit 12 may perform communication in the same scheme so that the first communication path L1 and the second communication path L2 are the same communication path.

Furthermore, with regard to the slave 10 of the energy management system of the present embodiment, the upper device 40 includes the upper server 42 and the master 41. The upper server 42 is a server computer configured to collect the meter-reading data from the energy meters 20 of the plurality of facilities 1 in a management area. The master 41 has the communication function with the upper server 42 and is configured to send to the upper server 42 the meter-reading data obtained from at least one of the facilities 1.

Additionally, the slave 10 of the energy management system of the present embodiment further includes the channel selector 102, the interference evaluator 103, and the change instructor 104. The channel selector 102 is configured to select the communication channels used by the second interface unit 12 and the third interface unit 13 from channels in the predetermined selectable range. The interference evaluator 103 is configured to evaluate the degree of interference through comparison of the prescribed threshold with the evaluation value indicative of the degree of interference in a case where the channel selected by the channel selector 102 is used. The change instructor 104 is configured to instruct the channel selector 102 to change the channel when the evaluation value is in a range, defined by the threshold, in which the degree of interference is relatively high.

Moreover, the slave 10 of the energy management system of the present embodiment further includes the identification information holding unit 101 configured to hold the identification information that is unique within the management area of the upper device 40. The channel selector 102 is configured to specify the channel based on the identification information held in the identification information holding unit 101 by use of the predetermined rule, and select the specified channel as the initial channel. The identification information holding unit 101 is configured to select the channel different from the initial channel as the communication channel when receiving the change instruction from the change instructor 104, and to select the channel same as the initial channel as the communication channel when not receiving the change instruction from the change instructor 104.

Further, in the slave 10 of the energy management system of the present embodiment, the change instructor 104 is configured to instruct the channel selector 102 to change the channel used by the second interface unit 12 from the current channel to an available channel that is less likely to cause interference when the third interface unit 13 acknowledges the start of use of the maintenance terminal 50 in a case where the channel used by the second interface unit 12 is same as the channel used by the maintenance terminal 50.

Moreover, the slave 10 of the energy management system of the present embodiment further includes the communication quality evaluator 105 and the power instructor 106. The communication quality evaluator 105 is configured to perform test communication by use of the channel selected by the channel selector 102 to evaluate the communication quality between the slave 10 and the electric appliance 31 through the communication path (second communication path L2). The power instructor 106 is configured to decrease the output power of the second interface unit 12 down to the allowable lower limit within the range in which the communication quality is kept fine.

Additionally, in the slave 10 of the energy management system of the present embodiment, the interference evaluator 103 has a function of detecting an available channel which is less likely to cause interference from the channels in the selectable range, and thereafter of providing the information of the detected available channel to the change instructor 104. The change instructor 104 is configured to instruct the channel selector 102 to change the current channel to one selected from the available channels indicated by the information provided from the interference evaluator 103.

Furthermore, in the slave 10 of the energy management system of the present embodiment, the channel selector 102 may select a frequency used for communication. Alternatively, the channel selector 102 may select a time slot used for communication. Alternatively, the channel selector 102 may select a combination of a frequency and a time slot used for communication.

Additionally, with regard to the slave 10 of the energy management system of the present embodiment, the identification information held in the identification information holding unit 101 is given by the upper device 40.

In other words, the slave 10 of the energy management system of the present embodiment includes the following first to fifteenth features. Note that, the second to fifteenth features are optional.

In the first feature, the slave 10 is a slave suitable for energy management systems for collecting, from the energy meter 20 for measuring an amount of electric energy supplied from the power source 70 to the predetermined place (facility 1) through the distribution line 60, the meter-reading data containing the amount of electric energy. The slave 10 includes the first interface unit 11, the second interface unit 12, the third interface unit 13, and the controller 100. The first interface unit 11 is configured to communicate with the upper device 40. The second interface unit 12 is configured to communicate with the electric appliance 31 installed in the predetermined place (facility 1). The third interface unit 13 is configured to communicate with the communication terminal 50. The controller 100 has: the function of obtaining the meter-reading data from the energy meter 20; the function of controlling the first interface unit 11 to send the meter-reading data to the upper device 40; and the function of controlling the third interface unit 13 to send the meter-reading data to the communication terminal 50. The second interface unit 12 and the third interface unit 13 are configured to perform wireless communication using electric waves in wireless communication schemes different from each other.

In the second feature based on the first feature, the wireless communication schemes are protocols.

In the third feature based on the first or second feature, the first interface unit 11 is connected to the upper device 40 through the distribution line 60, and is configured to perform power line communication with the upper device 40 through the distribution line 60.

In the fourth feature based on the third feature, the energy meter 20 is connected to the power source 70 through the transformer T1 configured to adjust electricity from the power source 70 to electricity appropriate to the predetermined place. The distribution line 60 includes the first path 61 between the power source 70 and the transformer T1, and the second path 62 between the transformer T1 and the energy meter 20. The upper device 40 is connected to the second path 62. The first interface unit 11 is configured to perform power line communication with the upper device 40 through the second path 62.

In the fifth feature based on any one of the first to fourth features, the first interface unit 11 is configured to perform wireless communication using an electric wave with the upper device 40.

In the sixth feature based on the fifth feature, the first interface unit 11 and the third interface unit 13 are configured to perform wireless communication in the same wireless communication scheme.

In the seventh feature based on the fifth feature, the first interface unit 11 and the second interface unit 12 are configured to perform wireless communication in the same wireless communication scheme.

In the eighth feature based on any one of the first to seventh features, the controller 100 includes the channel selector 102, the interference evaluator 103, and the change instructor 104. The channel selector 102 is configured to select a communication channel to be used for the wireless communication of at least one of the second interface unit 12 and the third interface unit 13, from a plurality of channels. The interference evaluator 103 is configured to judge whether interference of electric waves occurs in the communication channel. The change instructor 104 is configured to provide a change instruction to the channel selector 102 when the interference evaluator 103 determines that the interference occurs. The channel selector 102 is configured to change the communication channel in response to reception of the change instruction from the change instructor 104.

In the ninth feature based on the eighth feature, the controller 100 includes the identification information holding unit 101 storing identification information unique to the slave 10. The channel selector 102 is configured to select from the plurality of channels an initial channel as a candidate for the communication channel, depending on the identification information stored in the identification information holding unit 101. The channel selector 102 is configured to, when receiving the change instruction from the change instructor 104, select from the plurality of channels a channel different from the initial channel, and set the selected channel as the communication channel. The channel selector 102 is configured to, when not receiving the change instruction from the change instructor 104, set the initial channel as the communication channel.

In the tenth feature based on the eighth or ninth feature, the interference evaluator 103 is configured to judge whether the plurality of channels includes at least one available channel that does not cause interference of the electric wave. The interference evaluator 103 is configured to, when determining that the plurality of channels includes the available channel, provide available channel information identifying the at least one available channel to the change instructor 104. The change instructor 104 is configured to select a designated available channel to be set as the communication channel from the at least one available channel identified by the available channel information, and provide the change instruction indicating the designated available channel to the channel selector 102. The channel selector 102 is configured to, when receiving the change instruction from the change instructor 104, set the designated available channel indicated by the change instruction as the communication channel.

In the eleventh feature based on any one of the eighth to tenth features, the controller 100 further includes the communication quality evaluator 105 and the power instructor 106. The communication quality evaluator 105 is configured to evaluate the communication quality of the communication channel selected by the channel selector 102. The power instructor 106 is configured to set the intensity of the electric wave allocated to the communication channel to the lower limit of the range of intensities allowing the communication quality evaluated by the communication quality evaluator 105 to satisfy a predetermined condition.

In the twelfth feature based on any one of the eighth to eleventh features, the communication channel is a channel to be used in the wireless communication of the third interface unit 13. The channel selector 102 is configured to select the second communication channel to be used in the wireless communication of the second interface unit 12, from a plurality of channels. The third interface unit 13 is configured to judge whether use of the communication terminal 50 is started. The change instructor 104 is configured to, when the third interface unit 13 determines that use of the communication terminal 50 is started, provide to the channel selector 102 the change instruction that indicates, as the second communication channel, a channel that does not cause interference with a channel used by the communication terminal 50. The channel selector 102 is configured to, when receiving the change instruction from the change instructor 104, change the second communication channel to the channel indicated by the change instructor 104.

In the thirteenth feature based on any one of the eighth to twelfth features, each of the plurality of channel is defined by a frequency, a time slot, or a combination of a frequency and a time slot.

In the fourteenth feature based on the ninth feature, the identification information is given by the upper device 40 to the slave 10.

In the fifteenth feature based on any one of the first to fourteenth features, the slave 10 is attached to the energy meter 20.

According to the slave 10 of the energy management system of the present embodiment described above, the slave 10 attached to the energy meter 20 has the function of communicating with the electric appliance 31 used in the facility 1 in addition to the function of communicating with the upper device 40 and the communication terminal 50, and hence it is possible to enable the energy management in addition to the meter-reading. Additionally, the slave 10 is configured to perform wireless communication with the communication terminal 50 and the electric appliance 31 and therefore installation of the slave 10 can be facilitated, and furthermore the slave 10 is configured to perform such wireless communication with the communication terminal 50 and the electric appliance 31 in different schemes and thus interference of communication can be prevented.

Further, the energy management system of the present embodiment includes the master 41, the slave 10, and the communication terminal 50. The master 41 has the function of communicating with the upper server 42 for obtaining the meter-reading data including the amount of energy measured by the energy meter 20 from the facility 1 in the management area, and has the function of transmitting the meter-reading data collected from at least one facility 1 to the upper server 42. The slave 10 is attached to the energy meter 20 and has the function of transmitting the meter-reading data to the master 41. The maintenance terminal 50 has the function of communicating with the slave 10 to obtain the meter-reading data. The slave 10 includes the first interface unit 11, the second interface unit 12, and the third interface unit 13. The first interface unit 11 is configured to communicate with the master 41 through the first communication path L1. The second interface unit 12 is configured to perform wireless communication with the electric appliance 31, that is one of electric appliances used in the facility 1 and has the communication function, through the second communication path L2 in which electric waves are used as the transmission medium. The third interface unit 13 is configured to perform wireless communication with the maintenance terminal 50 having at least a function of obtaining the meter-reading data through the third communication path L3 in which electric waves are used as the transmission medium. The second interface unit 12 and the third interface unit 13 are configured to perform communication in different schemes so that the second communication path L2 and the third communication path L3 are communication paths independent from each other.

In other words, the energy management system of the present embodiment includes the following sixteenth to eighteenth features. Note that, the seventeenth and eighteenth features are optional.

In the sixteenth feature, the energy management system includes the slave 10, the upper device 40, and the communication terminal 50. The slave 10 is configured to obtain, from the energy meter 20 for measuring an amount of electric energy supplied from the power source 70 to the predetermined place through the distribution line 60, the meter-reading data containing the amount of electric energy. The upper device 40 is configured to obtain the meter-reading data from the slave 10. The communication terminal 50 is configured to obtain the meter-reading data from the slave 10. The slave 10 includes the first interface unit 11, the second interface unit 12, the third interface unit 13, and the controller 100. The first interface unit 11 is configured to communicate with the upper device 40. The second interface unit 12 is configured to communicate with the electric appliance 31 installed in the predetermined place (facility 1). The third interface unit 13 is configured to communicate with the communication terminal 50. The controller 100 has: the function of obtaining the meter-reading data from the energy meter 20; the function of controlling the first interface unit 11 to send the meter-reading data to the upper device 40; and the function of controlling the third interface unit 13 to send the meter-reading data to the communication terminal 50. The second interface unit 12 and the third interface unit 13 are configured to perform wireless communication using electric waves in wireless communication schemes different from each other.

In the seventeenth feature based on the sixteenth feature, the upper device 40 includes the master 41 connected to the distribution line 60 and the upper server 42 connected to the master 41. The master 41 has the function of obtaining the meter-reading data from the slave 10, and the function of sending the meter-reading data obtained from the slave 10 to the upper server 42. The upper server 42 is configured to store the meter-reading data received from the master 41.

In the eighteenth feature based on the sixteenth or seventeenth feature, the communication terminal 50 has the function of communicating with the electric appliance 31.

According to the energy management system of the present embodiment described above, the slave 10 attached to the energy meter 20 has the function of communicating with the electric appliance 31 used in the facility 1 in addition to the function of communicating with the upper device 40 and the communication terminal 50, and hence it is possible to enable the energy management in addition to the meter-reading. Additionally, the slave 10 is configured to perform wireless communication with the communication terminal 50 and the electric appliance 31 and therefore installation of the slave 10 can be facilitated, and furthermore the slave 10 is configured to perform such wireless communication with the communication terminal 50 and the electric appliance 31 in different schemes and thus interference of communication can be prevented.

1. A slave suitable for energy management systems for collecting, from an energy meter for measuring an amount of electric energy supplied from a power source to a predetermined place through a distribution line, meter-reading data containing the amount of electric energy,
the slave comprising:
a first interface unit configured to communicate with an upper device;
a second interface unit configured to communicate with an electric appliance installed in the predetermined place;
a third interface unit configured to communicate with a communication terminal; and
a controller having: a function of obtaining the meter-reading data from the energy meter; a function of controlling the first interface unit to send the meter-reading data to the upper device; and a function of controlling the third interface unit to send the meter-reading data to the communication terminal, and
the second interface unit and the third interface unit being configured to perform wireless communication using electric waves in wireless communication schemes different from each other.

2. The slave suitable for energy management systems according to claim 1, wherein
the wireless communication schemes are protocols.

3. The slave suitable for energy management systems according to claim 1, wherein
the first interface unit is connected to the upper device through the distribution line, and is configured to perform power line communication with the upper device through the distribution line.

4. The slave suitable for energy management systems, according to claim 3, wherein:
the energy meter is connected to the power source through a transformer configured to adjust electricity from the power source to electricity appropriate to the predetermined place;
the distribution line includes a first path between the power source and the transformer, and a second path between the transformer and the energy meter;
the upper device is connected to the second path; and
the first interface unit is configured to perform power line communication with the upper device through the second path.

5. The slave suitable for energy management systems, according to claim 1, wherein
the first interface unit is configured to perform wireless communication using an electric wave with the upper device.

6. The slave suitable for energy management systems, according to claim 5, wherein
the first interface unit and the third interface unit are configured to perform wireless communication in the same wireless communication scheme.

7. The slave suitable for energy management systems, according to claim 5, wherein
the first interface unit and the second interface unit are configured to perform wireless communication in the same wireless communication scheme.

8. The slave suitable for energy management systems, according to claim 1, wherein:
the controller includes
a channel selector configured to select a communication channel to be used for the wireless communication of at least one of the second interface unit and the third interface unit, from a plurality of channels,
an interference evaluator configured to judge whether interference of electric waves occurs in the communication channel, and
a change instructor configured to provide a change instruction to the channel selector when the interference evaluator determines that the interference occurs; and
the channel selector is configured to change the communication channel in response to reception of the change instruction from the change instructor.

9. The slave suitable for energy management systems, according to claim 8, wherein:
the controller includes an identification information holding unit storing identification information unique to the slave;
the channel selector is configured to select from the plurality of channels an initial channel as a candidate for the communication channel, depending on the identification information stored in the identification information holding unit;
the channel selector is configured to, when receiving the change instruction from the change instructor, select from the plurality of channels a channel different from the initial channel, and set the selected channel as the communication channel; and
the channel selector is configured to, when not receiving the change instruction from the change instructor, set the initial channel as the communication channel.

10. The slave suitable for energy management systems, according to claim 8, wherein:
the interference evaluator is configured to judge whether the plurality of channels includes at least one available channel that does not cause interference of the electric wave;
the interference evaluator is configured to, when determining that the plurality of channels includes the available channel, provide available channel information identifying the at least one available channel to the change instructor;
the change instructor is configured to select a designated available channel to be set as the communication channel from the at least one available channel identified by the available channel information, and provide the change instruction indicating the designated available channel to the channel selector; and
the channel selector is configured to, when receiving the change instruction from the change instructor, set the designated available channel indicated by the change instruction as the communication channel.

11. The slave suitable for energy management systems, according to claim 8, wherein
the controller further includes
a communication quality evaluator configured to evaluate a communication quality of the communication channel selected by the channel selector, and
a power instructor configured to set an intensity of an electric wave allocated to the communication channel to a lower limit of a range of intensities allowing the communication quality evaluated by the communication quality evaluator to satisfy a predetermined condition.

12. The slave suitable for energy management systems, according to claim 8, wherein:
the communication channel is a channel to be used in the wireless communication of the third interface unit;
the channel selector is configured to select a second communication channel to be used in the wireless communication of the second interface unit, from a plurality of channels;
the third interface unit is configured to judge whether use of the communication terminal is started;
the change instructor is configured to, when the third interface unit determines that use of the communication terminal is started, provide to the channel selector the change instruction that indicates, as the second communication channel, a channel that does not cause interference with a channel used by the communication terminal; and
the channel selector is configured to, when receiving the change instruction from the change instructor, change the second communication channel to the channel indicated by the change instructor.

13. The slave suitable for energy management systems according to claim 8, wherein
each of the plurality of channel is defined by a frequency, a time slot, or a combination of a frequency and a time slot.

14. The slave suitable for energy management systems according to claim 9, wherein
the identification information is given by the upper device to the slave.

15. The slave suitable for energy management systems according to claim 1, wherein
the slave is attached to the energy meter.

16. An energy management system comprising:
a slave configured to obtain, from an energy meter for measuring an amount of electric energy supplied from a power source to a predetermined place through a distribution line, meter-reading data containing the amount of electric energy;
an upper device configured to obtain the meter-reading data from the slave;
a communication terminal configured to obtain the meter-reading data from the slave,
the slave including:
a first interface unit configured to communicate with the upper device;
a second interface unit configured to communicate with an electric appliance installed in the predetermined place;
a third interface unit configured to communicate with the communication terminal; and
a controller having: a function of obtaining the meter-reading data from the energy meter; a function of controlling the first interface unit to send the meter-reading data to the upper device; and a function of controlling the third interface unit to send the meter-reading data to the communication terminal, and
the second interface unit and the third interface unit being configured to perform wireless communication using electric waves in wireless communication schemes different from each other.

17. The energy management system according to claim 16, wherein:
the upper device includes a master connected to the distribution line and an upper server connected to the master;
the master has a function of obtaining the meter-reading data from the slave, and a function of sending the meter-reading data obtained from the slave to the upper server; and
the upper server is configured to store the meter-reading data received from the master.

18. The energy management system according to claim 16, wherein
the communication terminal has a function of communicating with the electric appliance.
